(19) United States
(12) Patent Application Publication
(10) Pub. No.: US 2013/0241362 A1
(43) Pub. Date: Sep. 19, 2013

(54) PIEZOELECTRIC DEVICE

(71) Applicant: NIHON DEMPA KOGYO CO., LTD., TOKYO (JP)

(72) Inventor: RYOICHI ICHIKAWA, SAITAMA (JP)

(73) Assignee: NIHON DEMPA KOGYO CO., LTD., TOKYO (JP)

(21) Appl. No.: 13/798,170

(22) Filed: Mar. 13, 2013

(30) Foreign Application Priority Data
Mar. 14, 2012 (JP) 2012-056677

(51) Int. Cl. H01L 41/047

(52) U.S. Cl. CPC H01L 41/047
USPC 310/367

(57) ABSTRACT

A piezoelectric device includes a piezoelectric vibrating piece and a base portion in a square shape with four sides viewed from the first surface. The base portion has two sides that face one another. The two sides include two pairs of castellations depressed toward a center side of the base portion and two pairs of side surface electrodes on the two pairs of castellations. The two pairs of side surface electrodes connect the first surface and the second surface. One pair among the two pairs of side surface electrodes connects to the pair of connecting electrodes and one pair of mounting terminals among the two pairs of mounting terminals. The mounting terminals are formed up to four corners of the base portion.

### CROSS REFERENCE TO RELATED APPLICATIONS

This application claims the priority benefit of Japan application serial no. 2012-056677, filed on Mar. 14, 2012. The entirety of the above-mentioned patent application is hereby incorporated by reference herein and made a part of this specification.

### TECHNICAL FIELD

This disclosure relates to a piezoelectric device where a plurality of lid portions and a plurality of base portions can be fabricated in a state of a wafer.

### DESCRIPTION OF THE RELATED ART

As disclosed in Japanese Unexamined Patent Application Publication No. 11-136062 (hereinafter referred to as Patent Literature 1), a piezoelectric device that includes a pair of base castellations and a pair of side surface electrodes are proposed. The pair of base castellations are disposed at two sides that face each other on a base portion and depressed at the center side of the base portion. The pair of side surface electrodes are formed at the pair of base castellations and connect a first surface and a second surface. The castellation is disposed at a center of a short side of the base portion, and a connecting electrode is formed at a portion near the castellation only.

However, the base portion of the piezoelectric device disclosed in Patent Literature 1 includes a corner portion that may be chipped due to an impact or similar cause, which is applied during conveyance. Additionally, when the piezoelectric device is mounted to a printed circuit board with a solder, the corner portion of the base portion may be chipped by bending the printed circuit board.

A need thus exists for a piezoelectric device which is not susceptible to the drawbacks mentioned above.

### SUMMARY

A piezoelectric device according to a first aspect includes a piezoelectric vibrating piece and a base portion in a square shape with four sides viewed from a first surface. The piezoelectric vibrating piece includes a pair of excitation electrodes on both principal surfaces, and a pair of extraction electrodes. The pair of extraction electrodes is extracted from the pair of excitation electrodes. The base portion includes a pair of connecting electrodes and two pairs of mounting terminals. The pair of connecting electrodes are disposed on the first surface at a side of the piezoelectric vibrating piece and connected to the pair of extraction electrodes. The two pairs of mounting terminals are disposed on a second surface. The second surface is an opposite surface of the first surface. The base portion has two sides that face one another. Two pairs of castellations and two pairs of side surface electrodes are formed at the two sides, the two pairs of castellations are depressed toward a center side of the base portion, and the two pairs of side surface electrodes are on the two pairs of castellations. The two pairs of side surface electrodes connect the first surface and the second surface. One pair among the two pairs of side surface electrodes connects to the pair of connecting electrodes and one pair of mounting terminals among the two pairs of mounting terminals. The mounting terminals are formed up to four corners of the base portion.

### BRIEF DESCRIPTION OF THE DRAWINGS

The foregoing and additional features and characteristics of this disclosure will become more apparent from the following detailed description considered with the reference to the accompanying drawings, wherein:

FIG. 1 is an exploded perspective view of a first piezoelectric device 100 of a first Embodiment;

FIG. 2A is a cross-sectional view taken along the line IIA-IIA of FIG. 1;

FIG. 2B is a bottom view of the first piezoelectric device 100;

FIG. 3 is a flowchart illustrating fabrication of the first piezoelectric device 100 of the first Embodiment;

FIG. 4 is a plan view of a quartz-crystal wafer 10W;

FIG. 5 is a plan view of a lid wafer 11W;

FIG. 6 is a plan view of a base wafer 12W;

FIG. 7 is a bottom view of the base wafer 12W;

FIG. 8A is a cross-sectional view of a first piezoelectric device 100′ taken along a line VIIIA-VIIIA of FIG. 8B illustrating a modification of the first Embodiment;

FIG. 8B is a bottom view of the first piezoelectric device 100′;

FIG. 9 is an exploded perspective view of a second piezoelectric device 200 of a second Embodiment;

FIG. 10A is a cross-sectional view taken along the line XA-XA of FIG. 9;

FIG. 10B is a bottom view of the second piezoelectric device 200;

FIG. 11 is a plan view of a quartz-crystal wafer 20W;

FIG. 12A is a plan view of a quartz-crystal vibrating piece 20 of a modification of the second Embodiment viewed from the +Y′ side;

FIG. 12B is a transparent view of the quartz-crystal vibrating piece 20′ of the modification of the second Embodiment viewed from the +Y′ side;

FIG. 12C is a plan view of a base portion 22′ of the modification of the second Embodiment viewed from the +Y′ side;

FIG. 12D is a transparent view of the base portion 22′ of the modification of the second Embodiment viewed from the +Y′ side;

FIG. 13 is a cross-sectional view taken along the line XIII-XIII of FIG. 12B;

FIG. 14 is a plan view of a quartz-crystal wafer 20′W; and

FIG. 15 is a plan view of a base wafer 22W′.

### DETAILED DESCRIPTION

In this disclosure, an AT-cut quartz-crystal vibrating piece as a piezoelectric vibrating piece is employed. The AT-cut quartz-crystal vibrating piece has a principal surface (in the Y-Z plane) that is tilted by 35° 15′ about the Y-axis of crystallographic axes (XYZ) in the direction from the Z-axis to the Y-axis direction around the X-axis. The new axes tilted with reference to the axis directions of the AT-cut quartz-crystal vibrating piece are denoted as the Y′-axis and the Z′-axis. This disclosure defines the longer side direction of a crystal unit as the X-axis direction, the height direction of the crystal unit as the Y′-axis direction, and the direction perpendicular to the X and Y′-axis directions as the Z′-axis direction.

### Overall Configuration of a Piezoelectric Device 100 According to a First Embodiment

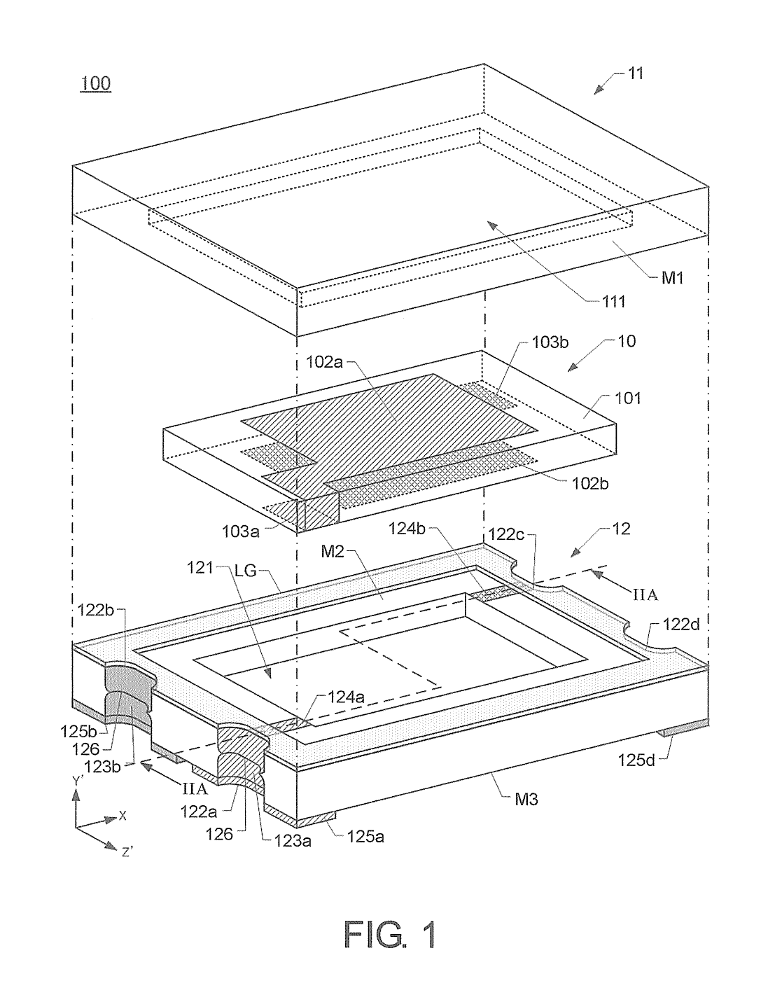

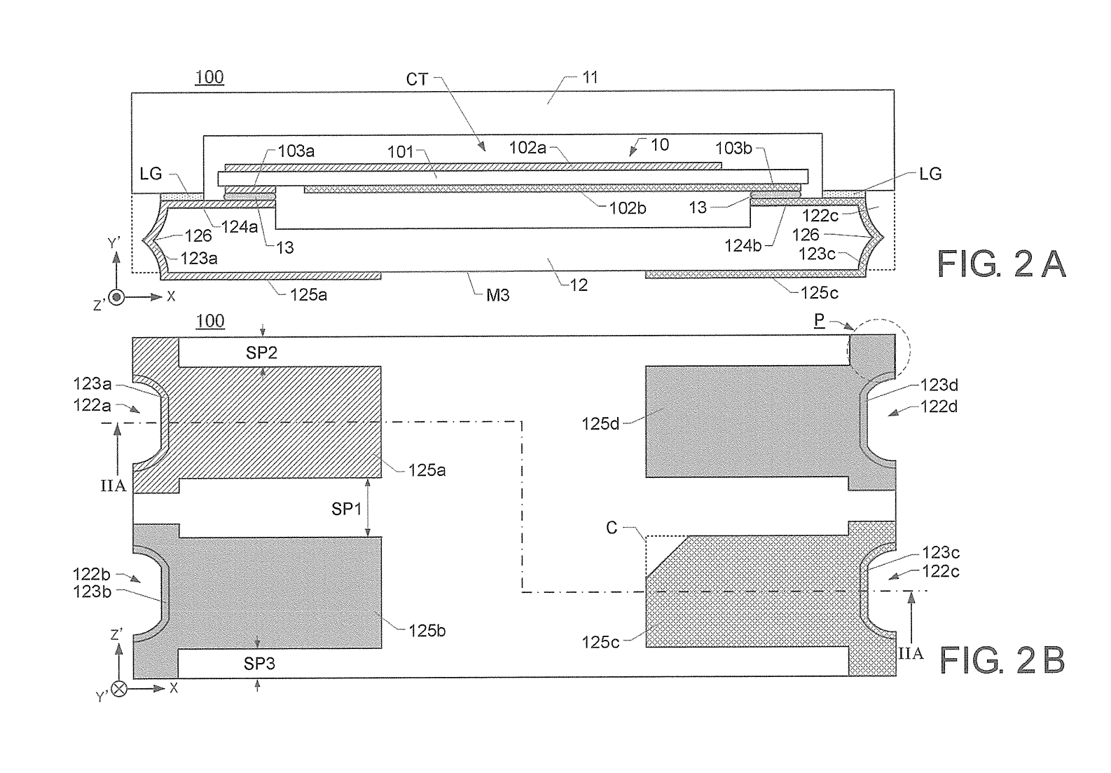

A description will be given of the overall configuration of the piezoelectric device 100 with referring to FIG. 1 to FIG. 2B. FIG. 1 is an exploded perspective view of the piezoelectric device 100, and FIG. 2A is a cross-sectional view taken along the line IIA-IIA of FIG. 1. In FIG. 1, a low-melting point glass LG, which is a sealing material, is transparent such that the whole connecting electrodes 124a and 124b are viewable.

As illustrated in FIG. 1 to FIG. 2B, the piezoelectric device 100 includes a lid portion 11, a base portion 12, and a planar quartz-crystal vibrating piece 10. The lid portion 11 includes a lid depressed portion 111. The base portion 12 includes a base depressed portion 121. The quartz-crystal vibrating piece 10 is placed on the base portion 12.

The quartz-crystal vibrating piece 10 includes an AT-cut crystal wafer 101. A pair of excitation electrodes 102a and 102b face each other and are disposed on both principal surfaces of the crystal wafer 101 close to the center of the surface. An extraction electrode 103a, which extends to the −X side of the bottom surface of the crystal wafer 101 (+Z′ side), connects to an excitation electrode 102a. An extraction electrode 103b, which extends to the +X side of the bottom surface of the crystal wafer 101 (−Z′ side), connects to an excitation electrode 102b. The quartz-crystal vibrating piece 10 may be a mesa type or an inverse mesa type.

Here, the excitation electrodes 102a and 102b and the extraction electrodes 103a and 103b, for example, employ a chromium layer as a foundation layer and a gold layer over the top surface of the chromium layer. The chromium layer has a thickness of, for example, 0.05 μm to 0.1 μm, and the gold layer has a thickness of, for example, 0.2 μm to 2 μm.

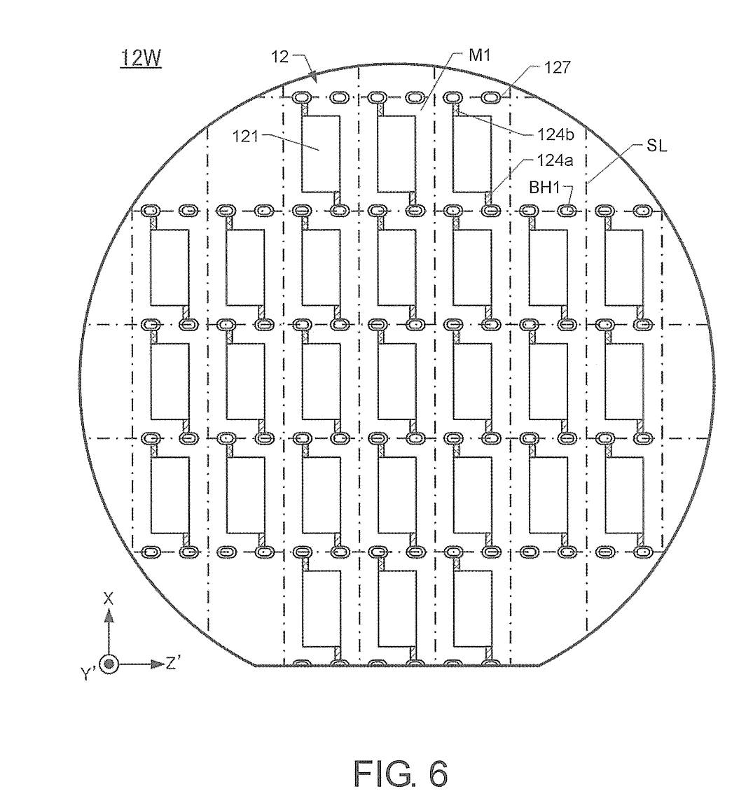

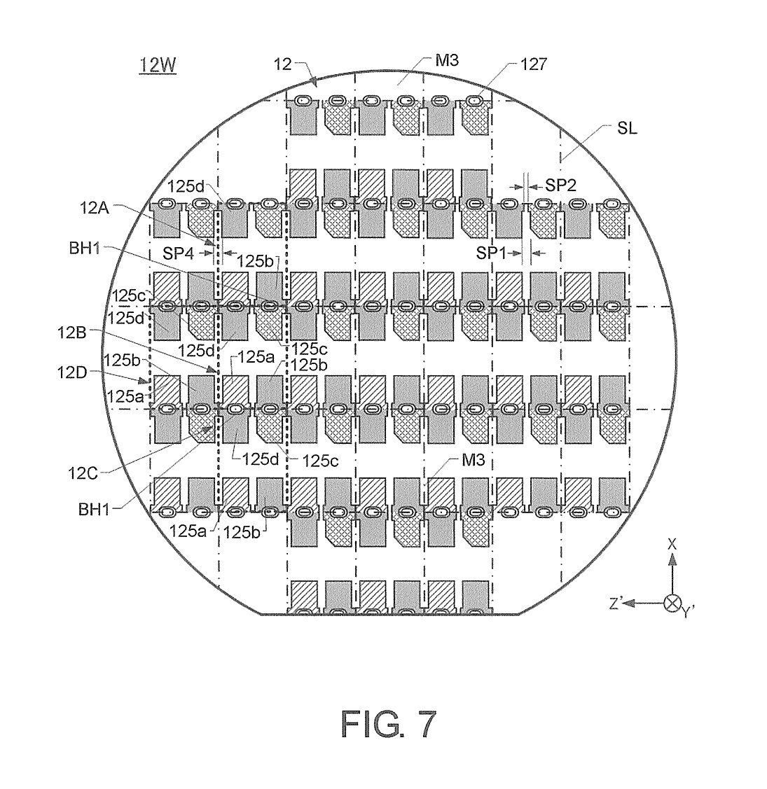

The base portion 12 is made of a glass or a piezoelectric material. The base portion 12 includes a second end surface M2, which is formed at a peripheral area of a base depressed portion 121, on its surface (+Y′ side surface). The base portion 12 also includes two base castellations 122a and 122b at the one side in the −X-axis direction. When a base through hole BH1 (see FIG. 6 and FIG. 7) is formed, the base castellations 122a and 122b extend in the Z′-axis direction. Here, the base castellation 122a is formed at the +Z side, and the base castellation 122b is formed at the −Z side. Similarly, the base portion 12 includes two other base castellations 122c and 122d at the other side in the +X-axis direction. When the base through hole BH1 (see FIG. 6 and FIG. 7) is formed, the base castellations 122c and 122d extend in the Z′-axis direction. Here, the base castellation 122c is formed at the −Z side, and the base castellation 122d is formed at the +Z side. That is, the base castellations 122a and 122c are diagonally disposed on the base portion 12, and the base castellations 122b and 122d are diagonally disposed on the base portion 12.

In the base portion 12, tapered projecting portions 126 are formed on the respective base castellations 122a to 122d. The projecting portion 126 protrudes outside at the approximately center portion in the Y′-axis direction. Additionally, the respective base castellations 122a to 122d include base side surface electrodes 123a to 123d.

In this constitution, the base castellations 122a to 122d include an inclined region. This shortens time the taken for forming a film when forming the base side surface electrodes 123a to 123d by a method such as sputtering.

A pair of connecting electrodes 124a and 124b is formed on the second end surface M2 of the base portion 12. The connecting electrode 124a electrically connects to the base side surface electrode 123a. The connecting electrode 124b electrically connects to a base side surface electrode 123c, which is diagonally disposed on the base portion 12 relative to the base side surface electrode 123a.

Further, the base portion 12 includes two pairs of mounting terminals 125a to 125d on a mounting surface M3 that are electrically connected to the respective base side surface electrodes 123a to 123d. The two pairs of mounting terminals 125a to 125d are formed on the four corners (the four corner portions) of the base portion 12. The corner portions of the base portion 12 are easily chipped; therefore, the mounting terminals are formed up to the four corners to increase strength (see the round frame P in FIG. 2B).

Among the two pairs of mounting terminals 125a to 125d, one pair of mounting terminals 125a and 125c are diagonally disposed on the base portion 12 and connects to the respective connecting electrodes 124a and 124b via the base side surface electrodes 123a and 123c. The mounting terminals 125a and 125c are mounting terminals for an external electrode (hereafter referred to as external electrodes). In short, the external electrodes 125a and 125c are diagonally disposed on the base portion 12. The external electrode 125c has a notch C (see FIG. 2B). The notch is formed to check the orientation of the piezoelectric device 100. When an alternating voltage (a potential that alternates between positive and negative values) is applied across the external electrodes 125a and 125c, the quartz-crystal vibrating piece 10 exhibits thickness-shear vibration.

On the other hand, among the two pairs of mounting terminals 125a to 125d, the other one pair is mounting terminals for grounding electrodes 125b and 125d (hereafter referred to as grounding electrodes), which are connected to base side surface electrodes 123b and 123d for grounding. In short, the grounding electrodes 125b and 125d are diagonally disposed in a direction different from the external electrodes 125a and 125c on the base portion 12. Here, the grounding electrodes 125b and 125d are employed for grounding; however, this disclosure includes the case where the grounding electrodes 125b and 125d are employed as terminals that are not electrically connected. The grounding electrodes 125b and 125d are employed to strongly bond the piezoelectric device 100 and a mounting printed circuit board (not shown) together.

The pair of external electrodes 125a and 125c and the pair of grounding electrodes 125b and 125d are disposed away from each other as illustrated in FIG. 2B. The external electrode 125a and the grounding electrode 125d contact the corner portion of the base portion 12. The external electrode 125a and the grounding electrode 125d are formed toward the center of the base portion 12 in the X-axis direction separated from one side in the +Z′ side by a distance SP2. The grounding electrode 125b and the external electrode 125c contact the corner portion of the base portion 12. The grounding electrode 125b and the external electrode 125c are formed toward the center of the base portion 12 in the X-axis direction separated from another side in the −Z′ side by a distance SP3.

A distance SP1 between the external electrode 125a and the grounding electrode 125b, and between the external electrode 125c and the grounding electrode 125d in the Z′-axis direction is, for example, approximately 200 μm to 500 μm. Additionally, a distance SP2 between the external electrode 125a or the grounding electrode 125d and one side at the +Z′ side of the base portion 12; and the distance SP3 between the grounding electrode 125b or the external electrode 125c and the other side at the −Z′ side of the base portion 12 are, for example, approximately 100 μm to 150 μm.

In the piezoelectric device 100, the length of the quartz-crystal vibrating piece 10 in the X-axis direction is longer than the length of the base depressed portion 121 in the X-axis direction. Accordingly, when the quartz-crystal vibrating piece 10 is placed on the base portion 12 with conductive adhesive 13, both ends of the quartz-crystal vibrating piece 10 in the X-axis direction is placed on the second end surface M2 of the base portion 12 as illustrated in FIG. 2A. At this time, the extraction electrodes 103a and 103b of the quartz-crystal vibrating piece 10 electrically connect to the respective connecting electrodes 124a and 124b of the base portion 12.

The lid portion 11 includes the lid depressed portion 111 and a first end surface M1. The lid depressed portion 111 has an area larger than the base depressed portion 121 in the X-Z′ plane. The first end surface M1 is formed at the peripheral area of the lid depressed portion 111. When the first end surface M1 of the lid portion 11 and the second end surface M2 of the base portion 12 are bonded together, the lid depressed portion 111 and the base depressed portion 121 form a cavity CT. The cavity CT houses the quartz-crystal vibrating piece 10. The cavity CT is filled with an inert gas or is evacuated to a vacuum state.

Here, the first end surface M1 of the lid portion 11 is bonded to the second end surface M2 of the base portion 12, for example, with a low-melting point glass LG, which is a sealing material (non-conductive adhesive).

In the lid portion 11, the length of the lid depressed portion 111 in the X-axis direction is longer than the length of the quartz-crystal vibrating piece 10 in the X-axis direction and the length of the base depressed portion 121 in the X-axis direction. Further, the low-melting point glass LG bonds the lid portion 11 and the base portion 12 together outside of the second end surface M2 (the width is approximately 300 μm) of the base portion 12 as illustrated in FIG. 1 and FIG. 2A.

While the quartz-crystal vibrating piece 10 is placed on the second end surface M2 of the base portion 12, the quartz-crystal vibrating piece 10 may be housed in the base depressed portion 121. At this time, the connecting electrodes extend from the base castellations 122a and 122c to the bottom surface of the base depressed portion 121 via the second end surface M2. In this case, the lid portion may be planar where a lid depressed portion is not formed.

### Fabrication Method of the Piezoelectric Device 100

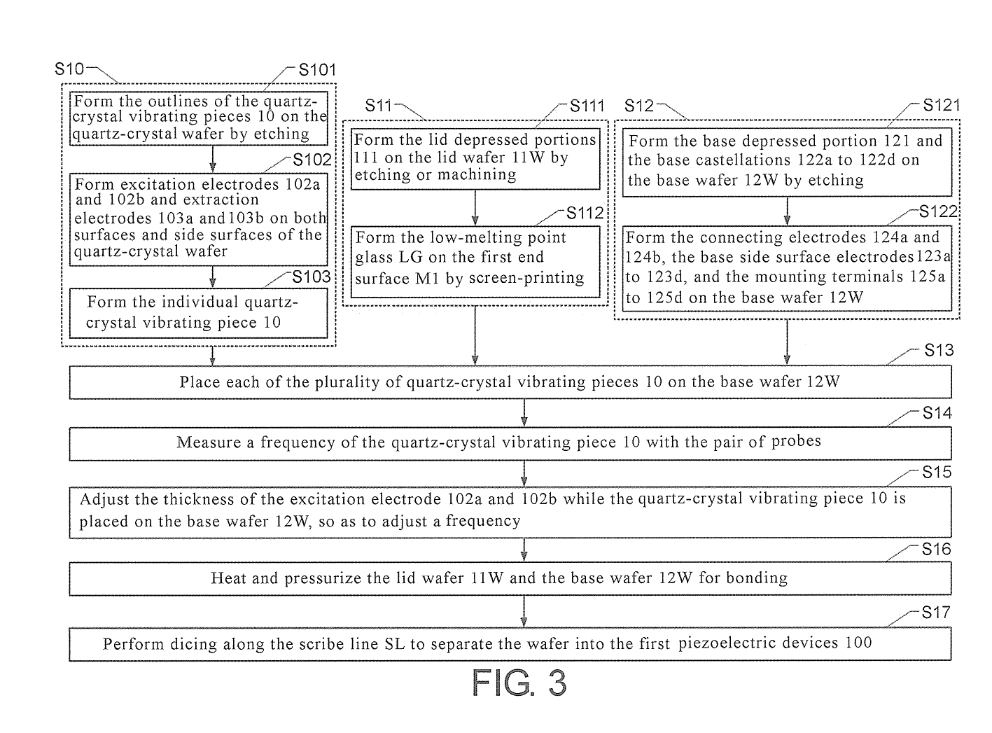

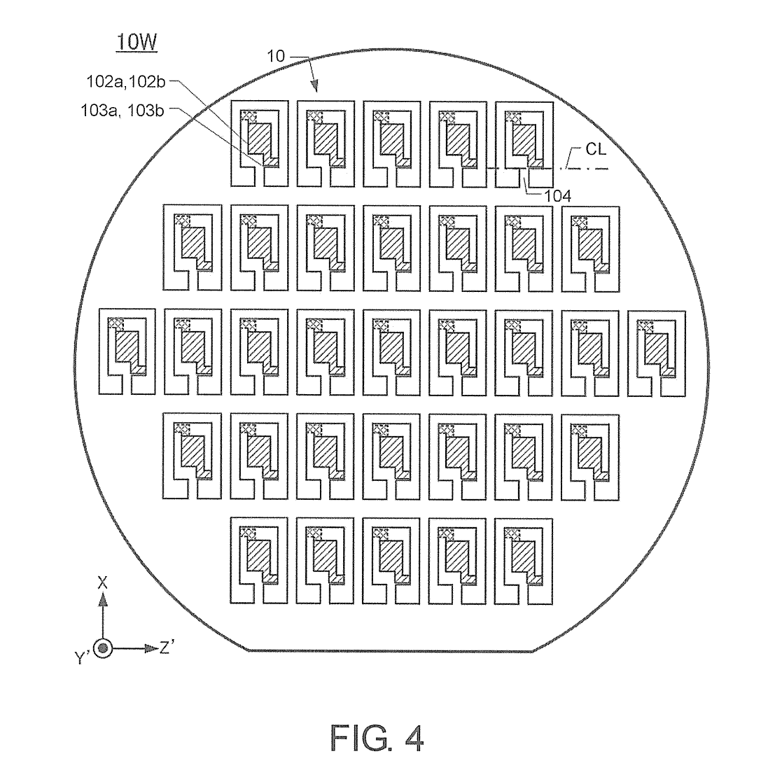

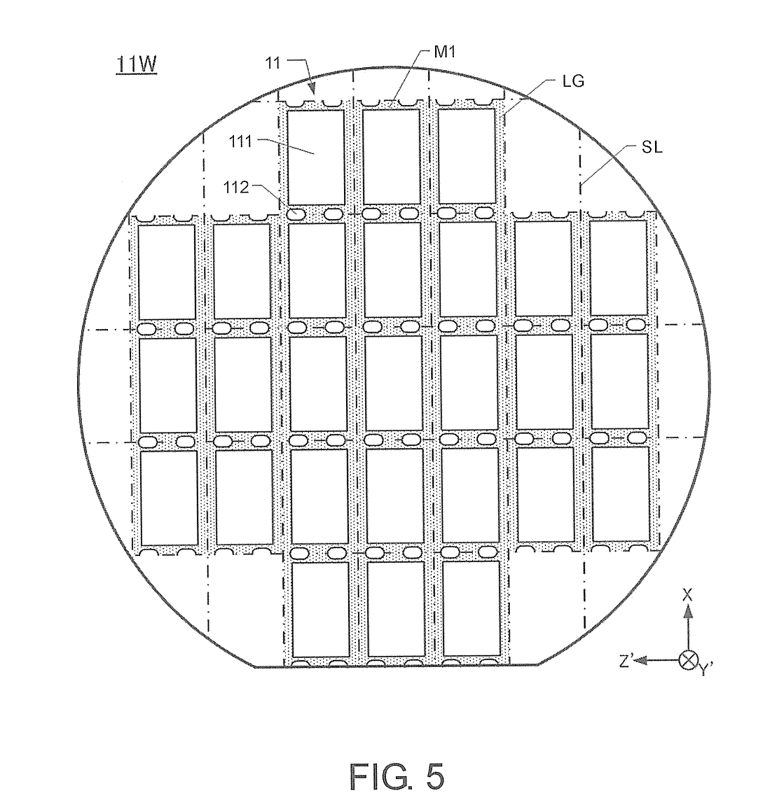

FIG. 3 is a flowchart illustrating fabrication of the piezoelectric device 100. In FIG. 3, the fabrication step of the quartz-crystal vibrating piece 10 (S10), the fabrication step of the lid portion 11 (S11), and the fabrication step of the base portion 12 (S12) can be performed at the same time. FIG. 4 is a plan view of a quartz-crystal wafer 10W where a plurality of quartz-crystal vibrating pieces 10 can be fabricated at the same time. FIG. 5 is a plan view of a lid wafer 11W where a plurality of lid portions 11 can be fabricated at the same time. FIG. 6 is a plan view of the base wafer 12W where a plurality of base portions 12 can be fabricated at the same time. FIG. 7 is a bottom view of the base wafer 12W.

The quartz-crystal vibrating piece 10 is fabricated at step S10. Step S10 includes steps S101 to S103. In step S101, outlines of the plurality of quartz-crystal vibrating pieces 10 are formed on the quartz-crystal wafer 10W of even thickness by etching as illustrated in FIG. 4. Here, each quartz-crystal vibrating piece 10 connects to the quartz-crystal wafer 10W with a connecting portion 104.

In step S102, first, a chromium layer and a gold layer are formed in this order on both of the surfaces and the side surfaces of the quartz-crystal wafer 10W by sputtering or vacuum evaporation. Then, a photoresist is evenly applied over all surfaces of the metal layer. Then, the patterns of the excitation electrode and the extraction electrode described on a photomask is exposed onto the quartz-crystal wafer 10W using all exposing device (not shown). Next, the metal layer exposed from the photoresist is etched. This forms excitation electrodes 102a and 102b and extraction electrodes 103a and 103b on both surfaces and the side surfaces of the quartz-crystal wafer 10W as illustrated in FIG. 4.

In step S103, the quartz-crystal vibrating pieces 10 are diced into individual pieces. In the dicing process, the quartz-crystal vibrating pieces 10 are diced along a cut line CL indicated by the one dot chain line illustrated in FIG. 4 using a dicing unit employing a laser beam, a dicing blade, or similar.

In step S11, the lid portion 11 is fabricated. Step S11 includes steps S111 and S112. In step S111, several hundred to several thousand of the lid depressed portions 111 are formed on the lid wafer 11W of crystal planar with even thickness as illustrated in FIG. 5. The lid depressed portion 111 is formed on the lid wafer 11W by etching or machining. The first end surface M1 is formed at the peripheral area of the lid depressed portion 111.

In step S112, the low-melting point glass LG is printed on the first end surface M1 of the lid wafer 11W by screen-printing. Then, by temporary hardening of the low-melting point glass LG, the low-melting point glass LG film is formed on the first end surface M1 of the lid wafer 11W. The low-melting point glass film is not foamed on a portion 112 corresponding to the base through hole BH1 (the base castellations 122a to 122d in FIG. 1). In this embodiment, the low-melting point glass LG is formed on the lid portion 11; however, the low-melting point glass LG may be formed on the second end surface M2 of the base portion 12.

In step S12, the base portion 12 is fabricated. Step S12 includes steps S121 and S122. In step S121, several hundred to several thousand of the base depressed portions 121 are formed on the base wafer 12W of crystal planar with even thickness as illustrated in FIG. 6. The base depressed portion 121 is formed on the base wafer 12W by etching. The second end surface M2 is formed at the peripheral area of the base depressed portion 121. At the same time, two base through holes BH1 are formed on both sides of each base portion 12 in the X-axis direction. The base through hole BH1 has a rounded rectangular shape and penetrates the base wafer 12W.

In step S121, the base castellations 122a to 122d are formed by etching from the +Y′ side and the −Y′ side. When etching is performed from the +Y′ side, the base depressed portion 121 is formed at the same time. This forms a projecting region 127 at the base through hole BH1 of the base wafer 12W as illustrated in FIG. 6. Dividing the projecting region 127 into half forms the projecting portion 126 (see FIG. 1 and FIG. 6). Here, when the base through hole BH1 of the rounded rectangular shape is divided into half, one of the base castellations 122a to 122d is formed (see FIG. 1).

In step S122, sputtering from the +Y′ side and the −Y′ side forms the base side surface electrodes 123a to 123d at the base castellations 122a to 122d.

In step S122, gold (Au) layers are formed on the surfaces of chromium (Cr) layers, which are foundation layers, at both surfaces of the base wafer 12W by sputtering. Then, etching forms the connecting electrodes 124a and 124b on the second end surface M2 as illustrated in FIG. 6.

At the same time, a pair of external electrodes 125a and 125c and a pair of grounding electrodes 125b and 125d are formed on the bottom surface of the base wafer 12W as illustrated in FIG. 7. Here, an external electrode and a grounding electrode formed adjacent each other in the X-axis direction are integrally formed at the base portion 12. Four base portions (12A to 12D) enclosed by the dotted line in FIG. 7 will be described as one example. The external electrode 125a of a base portion 12B, the grounding electrode 125d of a base portion 12C, and the base side surface electrodes 123a and 123d of the base through hole BH1 are integrally formed. Further, the external electrode 125c of the base portion 12B, the grounding electrode 125b of the base portion 12A, and the base side surface electrodes 123b and 123c of the base through hole BH1 are integrally formed. These electrodes employ a chromium (Cr) layer as a foundation layer and nickel tungsten (Ni/W) alloy is sputtered. Then a gold (Au) layer is formed on the sputtered surface.

Additionally, mounting terminals of the base portion 12B (the external electrode and the grounding electrode) are formed away from mounting terminals of the base portion 12D, which is adjacent to the base portion 12B in the Z′-axis direction, by a distance SP4. Here, the distance SP4 is approximately 240 μm to 280 μm. Assuming that, for example, the distance SP4 is 240 μm and the width for dicing in step S17, which will be described below, is 40 μm. The distance SP3 indicated in FIG. 2B becomes 100 μm. That is, an external electrode and a grounding electrode formed adjacent to each other on the base portion 12 in the X-axis direction are connected, while an external electrode and a grounding electrode formed adjacent to each other on the base portion 12 in the Z′-axis direction are not connected. On the other hand, mounting terminals corresponding to the four corners (the corner portions) of the base portion 12B and the base portion 12D are formed in contact with each other in the Z′-axis direction. This is because even if a dicing width changes, the mounting terminals 125a to 125d are formed up to the four corners (the four corner portions) of the base portion 12.

In step S13, the individual quartz-crystal vibrating piece 10, which is fabricated in step S10, is placed on the second end surface M2 of the base portion 12 formed on the base wafer 12W with the conductive adhesive 13. At this time, the quartz-crystal vibrating piece 10 is placed on the second end surface M2 of the base portion 12 so as to align the extraction electrodes 103a and 103b of the quartz-crystal vibrating piece 10 with the respective connecting electrodes 124a and 124b of the second end surface M2 of the base portion 12. Thus, several hundred to several thousand of the quartz-crystal vibrating pieces 10 are placed on the base wafer 12W.

In step S14, a pair of probes for frequency measurement (not shown) contact the pair of respective external electrodes 125a and 125c on the same base portion 12, and thus the frequency of each quartz-crystal vibrating piece 10 is measured.

In step S15, the thickness of the excitation electrode 102a of the quartz-crystal vibrating piece 10 is adjusted. The thickness can be adjusted by sputtering a metal onto the excitation electrode 102a to increase its mass (and to decrease its frequency), or by evaporating metal from the excitation electrode 102a to decrease its mass (and to increase its frequency) by reverse sputtering. The details of the frequency adjustment are disclosed in Japanese Unexamined Patent Application Publication No. 2009-141825 by the applicants of this application. If the measured frequency result is within its predetermined range, adjustment of the frequency is not required.

In step S14, after a frequency of one quartz-crystal vibrating piece 10 is measured, the frequency of one quartz-crystal vibrating piece 10 may be adjusted in step S15. The sequence of this step is repeated for all the quartz-crystal vibrating pieces 10 on the base wafer 12W. Alternatively, after a frequency of all the quartz-crystal vibrating pieces 10 on the base wafer 12W is measured in step S14, the frequency of the quartz-crystal vibrating pieces 10 may be adjusted one by one in step S15.

In step S16, the low-melting point glass LG is heated, and the lid wafer 11W and the base wafer 12W are pressurized. Thus, the lid wafer 11W and base wafer 12W are bonded together by the low-melting point glass LG.

In step S17, the bonded-together lid wafer 11W and the base wafer 12W are individually diced. In the dicing process, using a dicing unit employing a laser beam, a dicing blade, or similar, separates the wafer into individual piezoelectric devices 100 by dicing along the scribe lines SL, denoted by the one dot chain line illustrated in FIGS. 5 to 7. This fabricates several hundred to several thousand of the piezoelectric devices 100. As illustrated in FIG. 7, a part of the mounting terminals corresponding to the four corners (the corner portions) of the base portion 12 contacts in the Z′-axis direction while other parts are formed providing the distance SP4. In view of this, at usage of a dicing blade, clogging the blade with a metal (so-called clogging) is reduced to a minimum.

### Overall Configuration of a First Piezoelectric Device 100′ According to a Modification of the First Embodiment

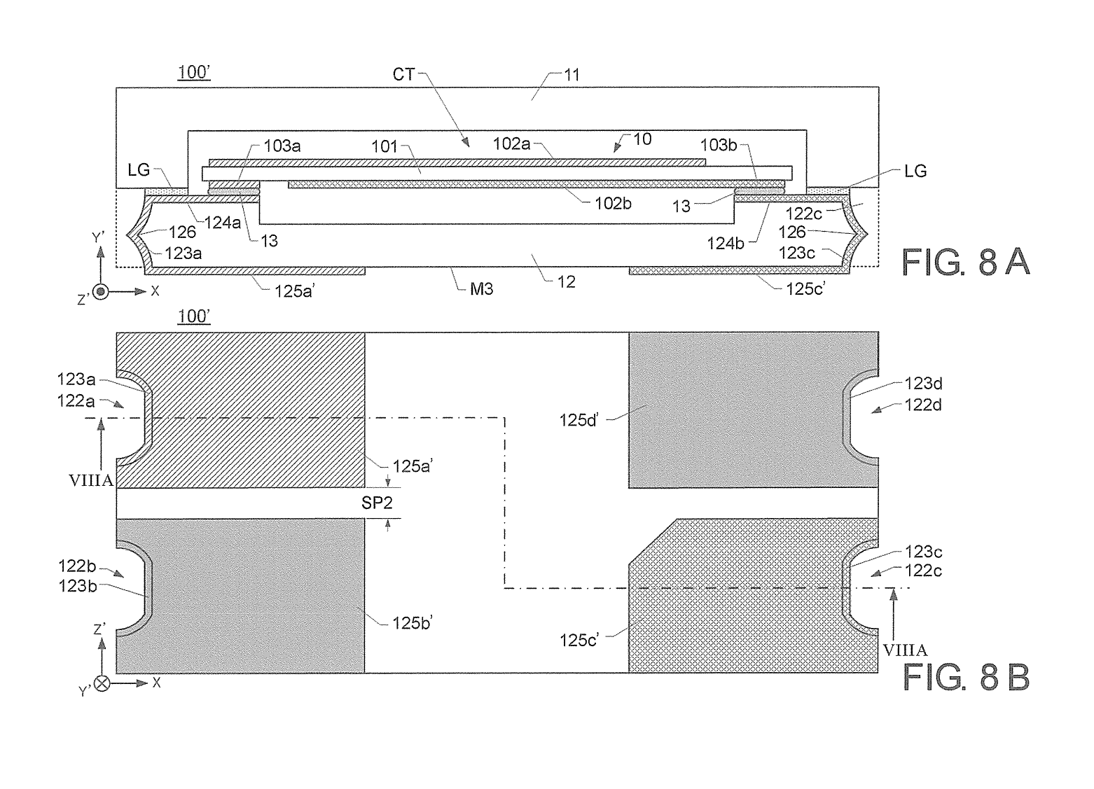

A description will be given of the overall configuration of the first piezoelectric device 100′ with referring to FIG. 8A and FIG. 8B. FIG. 8A is a cross-sectional view of the first piezoelectric device 100′ taken along a line VIIIA-VIIIA of FIG. 8B illustrating a modification of the first Embodiment. FIG. 8B is a bottom view of the first piezoelectric device 100′.

As illustrated in FIG. 8B, the first piezoelectric device 100′ includes an external electrode and a grounding electrode of a different shape with those of the first piezoelectric device 100. The embodiment will now be described wherein like reference numerals designate corresponding or identical elements with the first piezoelectric device 100 throughout the embodiments.

A base portion 12′ includes two pairs of mounting terminals 125a′ to 125d′ on a mounting surface M3. The two pairs of mounting terminals 125a′ to 125d′ electrically connect to the respective base side surface electrodes 123a to 123d. Each of the two pairs of mounting terminals 125a′ to 125d′ extends to the corner portion, one side at the +Z′ side, and one side at the −Z′ side of the base portion 12′ to enhance a strength of the four corners (see FIG. 8B).

Among the two pairs of mounting terminals 125a′ to 125d′, one pair are external electrodes 125a′ and 125c′ that are diagonally disposed on the base portion 12′ and connect to the respective connecting electrodes 124a and 124b via the base side surface electrodes 123a and 123c. The external electrode 125c′ includes a notch (see FIG. 8B) to check the orientation of the piezoelectric device 100′.

The pair of external electrodes 125a′ and 125c′ and the pair of grounding electrodes 125b′ and 125d′ are disposed away from each other as illustrated in FIG. 8B. The external electrode 125a′ and the grounding electrode 125d′ are formed in contact with the corner portion and one side at the +Z′ side of the base portion 12′. The grounding electrode 125b′ and the external electrode 125c′ are formed in contact with the corner portion and the other side at the −Z′ side of the base portion 12′. Here, the distance SP2 between the external electrode 125a′ and the grounding electrode 125b′ or between the external electrode 125c′ and the grounding electrode 125d′ in the Z′-axis direction is, for example, approximately 100 μm to 150 μm.

FIG. 8A and FIG. 8B illustrate the two pairs of mounting terminals 125a′ to 125d′ according to the first Embodiment, this applies to a modification of the second Embodiment, which will be described below.

### Overall Configuration of a Second Piezoelectric Device 200 According to a Second Embodiment

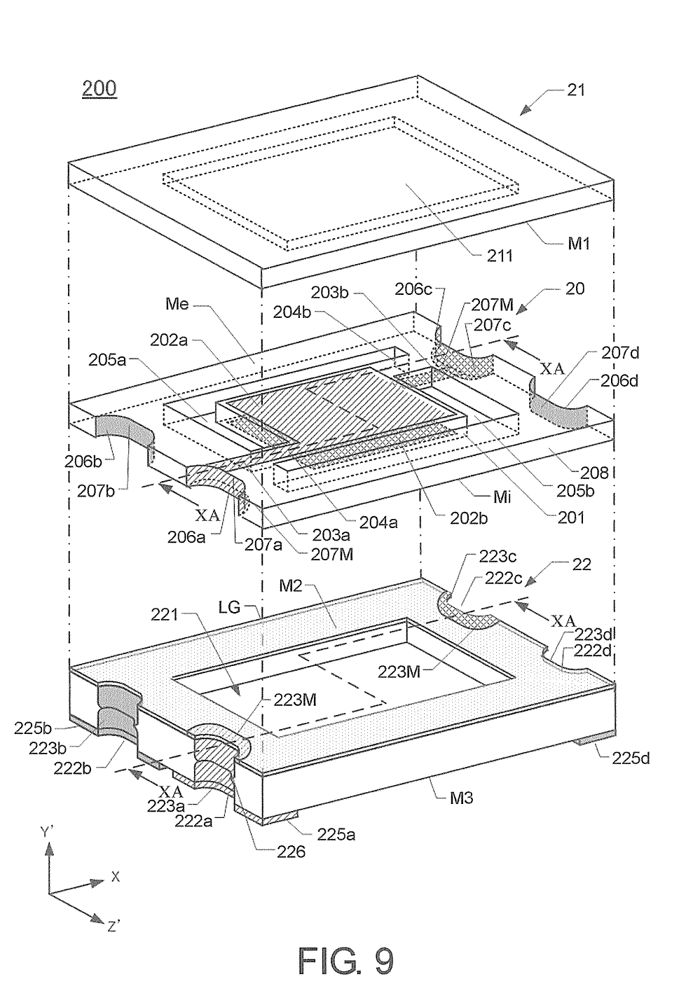

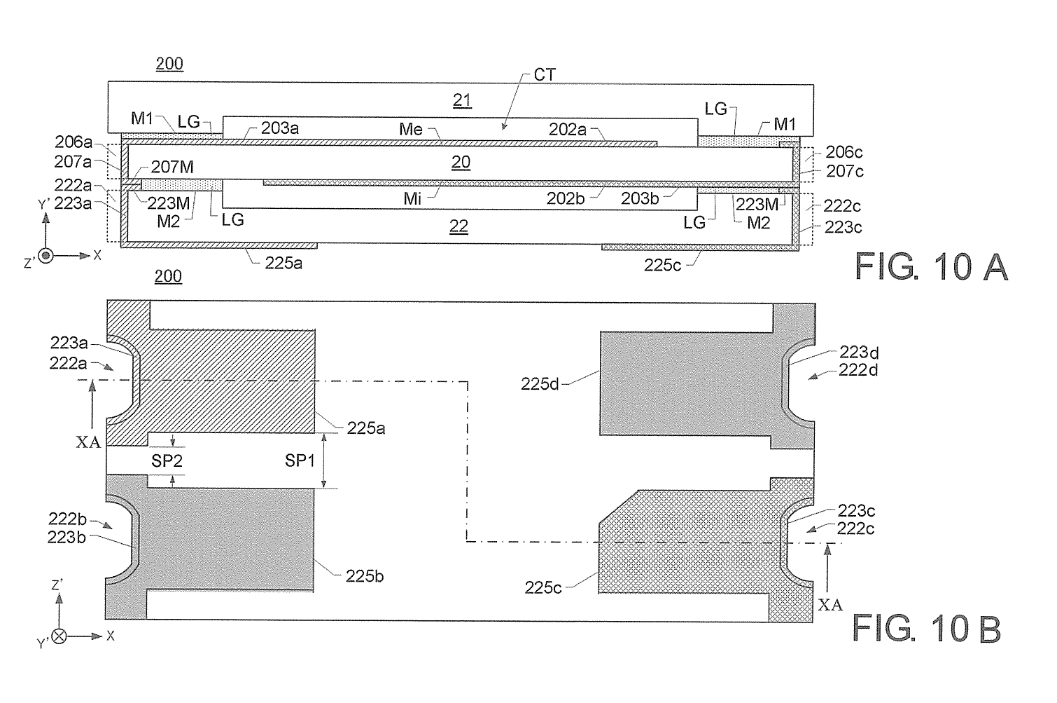

A description will be given of the overall configuration of the second piezoelectric device 200 with referring to FIG. 9, FIG. 10A, and FIG. 10B. FIG. 9 is an exploded perspective view of the second piezoelectric device 200. FIG. 10A is a cross-sectional view taken along the line XA-XA of FIG. 9

As illustrated in FIG. 9 and FIG. 10A, the second piezoelectric device 200 includes a lid portion 21 that includes a lid depressed portion 211, a base portion 22 that includes a base depressed portion 221, and a rectangular quartz-crystal vibrating piece 20. The quartz-crystal vibrating piece 20 is sandwiched between the lid portion 21 and the base portion 22.

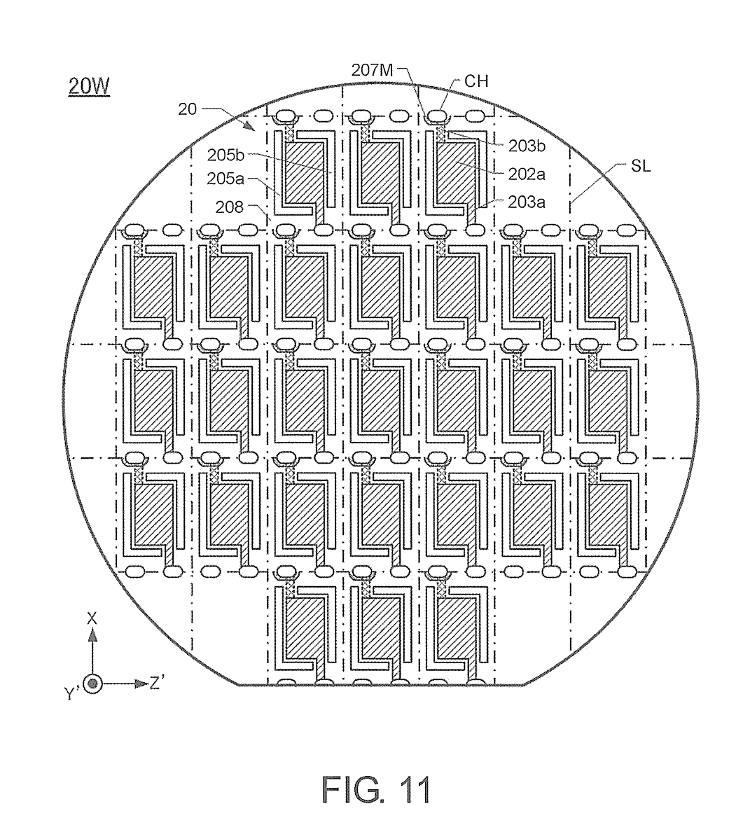

The quartz-crystal vibrating piece 20 includes a crystal vibrator 201 and a framing body 208 that surrounds the crystal vibrator 201. The crystal vibrator 201 includes excitation electrodes 202a and 202b on both of the surfaces. A pair of supporting portions 204a and 204b is formed between the crystal vibrator 201 and the framing body 208. The pair of respective supporting portions 204a and 204b extends from the crystal vibrator 201 along both of the sides in the X-axis direction and connects to the framing body 208. Accordingly, a pair of L-shaped through openings 205a and 205b is formed between the crystal vibrator 201 and the framing body 208. Two by two crystal castellations 206a to 206d are disposed on both sides in the X-axis direction of the quartz-crystal vibrating piece 20 when forming a crystal through hole CH of a rounded rectangular shape (see FIG. 11). Both of the sides extend in the Z′-axis direction. The crystal castellations 206a to 206d include crystal side surface electrodes 207a to 207d, respectively.

A supporting portion 204a includes an extraction electrode 203a on its surface Me. The extraction electrode 203a connects an excitation electrode 202a and a crystal side surface electrode 207a, which is formed at the +Z side of one side in the −X-axis direction of the quartz-crystal vibrating piece 20. Here, the crystal side surface electrode 207a extends to a back surface Mi of the quartz-crystal vibrating piece 20 to form a connection pad 207M. The connection pad 207M securely and electrically connects to a connection pad 223M of a base side surface electrode 223a, which will be described below. Similarly, a supporting portion 204b includes an extraction electrode 203b on its back surface Mi. The extraction electrode 203b connects an excitation electrode 202b and a crystal side surface electrode 207c, which is formed at the −Z side of the other side in the +X-axis direction of the quartz-crystal vibrating piece 20. Here, the extraction electrode 203b is connected to a connection pad 223M of a base side surface electrode 223c that will be described below.

The base portion 22 is made of a glass or a quartz-crystal material, and includes a second end surface M2 formed at a peripheral area of the base depressed portion 221 on its surface (+Y′ side surface). Additionally, the base portion 22 includes two by two base castellations 222a to 222d when the base through holes BH1 (see FIG. 6 and FIG. 7) are formed on both of the sides in the X-axis direction. Furthermore, the base castellations 222a to 222d form respective base side surface electrodes 223a to 223d. Here, the base side surface electrode 223a formed at the +Z′ side of one side in the −X-axis direction of the base portion 22 is connected to the connection pad 207M via the connection pad 223M formed on the second end surface M2. The connection pad 207M is formed on a crystal side surface electrode 207a formed on the quartz-crystal vibrating piece 20. This connects the base side surface electrode 223a and the extraction electrode 203a together via the connection pad 207M and the crystal side surface electrode 207a. Further, the base side surface electrode 223c formed at the −Z side of another side in the +X-axis direction of the base portion 22 is connected to an extraction electrode 203b formed at the quartz-crystal vibrating piece 20.

On the other hand, the base portion 22 includes a pair of diagonally disposed external electrodes 225a and 225c and a pair of diagonally disposed grounding electrodes 225b and 225d on the mounting surface M3 (see FIG. 10A and FIG. 10B). The pair of external electrodes 225a and 225c and the pair of grounding electrodes 225b and 225d, as illustrated in FIG. 10B, are formed to be the same shape as the external electrode and the grounding electrode of the base portion 12 of the first piezoelectric device 100.

The pair of external electrodes 225a and 225c are respectively connected to the base side surface electrodes 223a and 223c, which are connected to the extraction electrodes 203a and 203b of the quartz-crystal vibrating piece 20. Additionally, the pair of grounding electrodes 225b and 225d are respectively connected to the other base side surface electrodes 223b and 223d. The mounting terminals 225a to 225d extend up to the four corners (four corner portions) of the base portion 22 to enhance the strength of the four corners (see FIG. 10B).

The external electrode 225c includes a notch (see FIG. 10B) to check the orientation of the piezoelectric device 200. As illustrated in FIG. 10A, the cavity CT that houses the crystal vibrator 201 of the quartz-crystal vibrating piece 20 is formed by the lid portion 21, the framing body 208 of the quartz-crystal vibrating piece 20, and the base portion 22. Here, between the lid portion 21 and the quartz-crystal vibrating piece 20, and between the quartz-crystal vibrating piece 20 and the base portion 22 are bonded together with a low-melting point glass LG, which is a sealing material.

### Fabrication Method of the Second Piezoelectric Device 200

The method for fabricating the second piezoelectric device 200 is approximately the same as the fabrication method illustrated in FIG. 3. The difference is that a dicing process, which individually dices the quartz-crystal vibrating pieces 10 illustrated in step S103, is eliminated in this method. Additionally, the low-melting point glass LG is disposed between both of the principal surfaces of the framing body 208 and the lid portion 21 and the base portion 22. Therefore, a detailed flowchart is omitted.

FIG. 11 is a plan view of a quartz-crystal wafer 20W where a plurality of quartz-crystal vibrating pieces 20 can be fabricated at the same time. As illustrated in FIG. 11, the quartz-crystal wafer 20W includes excitation electrodes 202a and 202b and the extraction electrodes 203a and 203b that are formed on both surfaces and side surfaces.

Overall Configuration of a Second Piezoelectric Device 200′ According to a Modification of the Second Embodiment

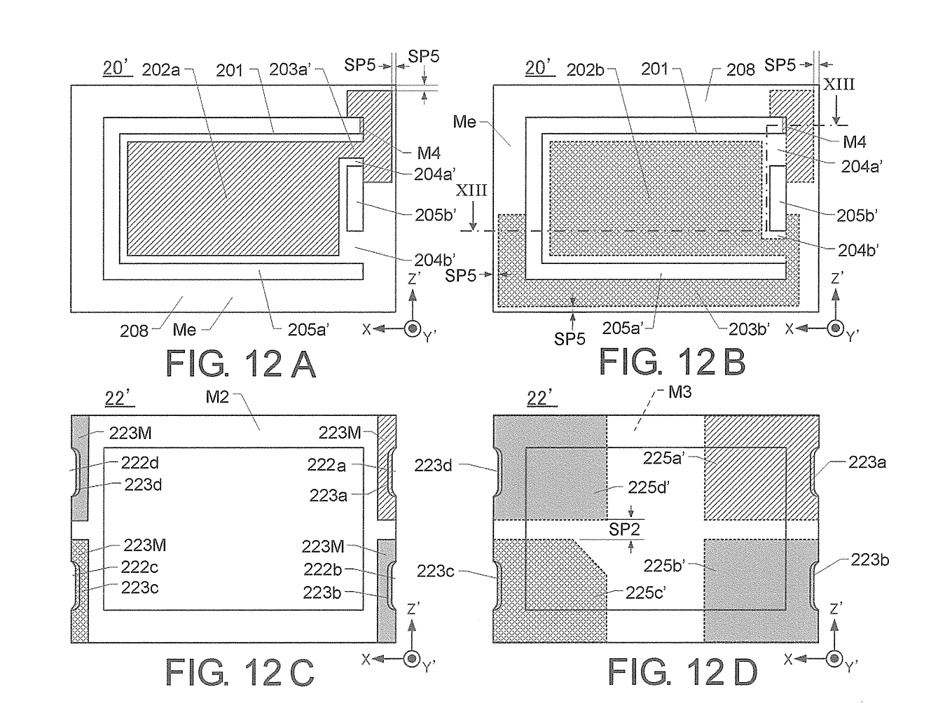

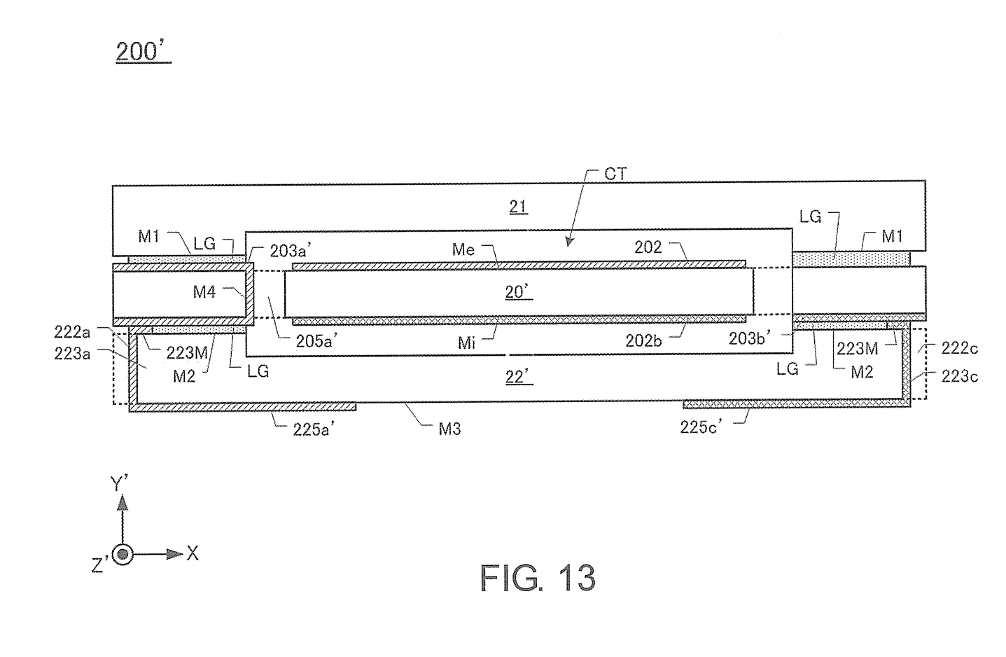

A description will be given of the overall configuration of the second piezoelectric device 200′ of a modification of the second Embodiment with referring to FIG. 12A to FIG. 12D and FIG. 13. FIG. 12A is a plan view of a quartz-crystal vibrating piece 20′ of a modification of the second Embodiment viewed from the +Y′ side. FIG. 12B is a transparent view of the quartz-crystal vibrating piece 20′ of the modification of the second Embodiment viewed from the +Y′ side. FIG. 12C is a plan view of a base portion 22′ of the modification of the second Embodiment viewed from the +Y′ side. FIG. 12D is a transparent view of the base portion 22′ of the modification of the second Embodiment viewed from the +Y′ side. FIG. 13 is a cross-sectional view taken along the line XIII-XIII of FIG. 12B.

As illustrated in FIG. 12A and FIG. 12B, a quartz-crystal vibrating piece 20′ of a second piezoelectric device 200′ includes the crystal vibrator 201 and the framing body 208. The crystal vibrator 201 includes excitation electrodes 202a and 202b on both surfaces. The framing body 208 surrounds the crystal vibrator 201. A pair of supporting portions 204a′ and 204b′, which each extends from the crystal vibrator 201 to the −X side, are formed between the crystal vibrator 201 and the framing body 208. Therefore, a rectangular through opening 205a′, which is opened at one side (−X side), is formed between the crystal vibrator 201 and the framing body 208. A rectangular through opening 205b′ is formed between the pair of supporting portions 204a′ and 204b′.

As illustrated in FIG. 13, an extraction electrode 203a′ is connected to an excitation electrode 202a formed on the surface Me of the quartz-crystal vibrating piece 20′. The extraction electrode 203a′ is extended from the front surface Me to the back surface Mi of the quartz-crystal vibrating piece 20′ via a side surface M4 of the through opening 205a′.

Referring to FIG. 12A, the extraction electrode 203a′ extending to the back surface Mi of the quartz-crystal vibrating piece 20′ is formed at one corner at the −X side and the +Z′ side of the quartz-crystal vibrating piece 20′. Since the quartz-crystal vibrating piece 20′ is fabricated in a state of a wafer, the extraction electrode 203a′ is formed providing a distance SP5 from one side at the +Z′ side of the quartz-crystal vibrating piece 20′ such that the extraction electrode 203a′ is not affected by the adjacent quartz-crystal vibrating piece 20′ at measurement of frequency.

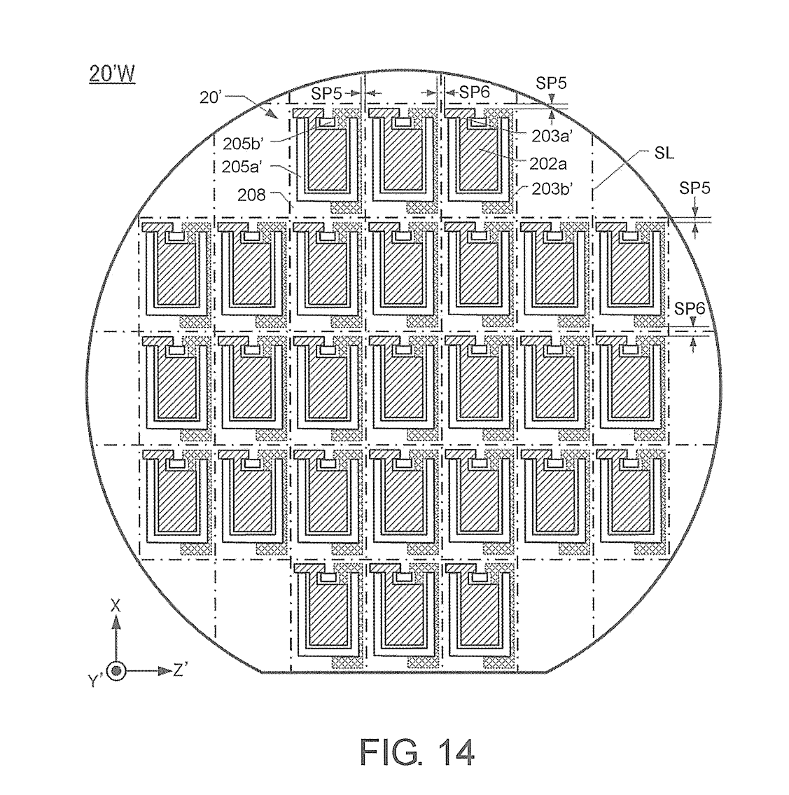

The extraction electrode 203b′ formed at the back surface Mi of the quartz-crystal vibrating piece 20′ extends from the −X side of the crystal vibrator 201, goes along the framing body 208, and is formed at another corner at the +X side and the −Z′ side of the quartz-crystal vibrating piece 20′. Here, as described in the second Embodiment, since the quartz-crystal vibrating piece 20′ is fabricated in a state of a wafer, the extraction electrode 203b′ is formed providing the distance SP5 from the other side at the −Z′ side of the quartz-crystal vibrating piece 20′ such that the extraction electrode 203b′ is not affected by the adjacent quartz-crystal vibrating piece 20′ (see FIG. 12B and FIG. 14).

As illustrated in FIG. 12C and FIG. 12D, the base portion 22′ of the modification of the second Embodiment includes two pairs of mounting terminals 225a′ to 225d′ that are electrically connected to the respective base side surface electrodes 223a to 223d on the mounting surface M3. The two pairs of mounting terminals 225a′ to 225d′ are formed to the four corners (the four corner portions) of the base portion 22′ to enhance strength of the four corners.

Among the two pairs of mounting terminals 225a′ to 225d′, one pair are external electrodes 225a′ and 225c′ that are diagonally disposed on the base portion 22′ and connect to the respective connection pad 223M via the base side surface electrodes 223a and 223c. The external electrode 225c′ includes a notch (see FIG. 12D) to check the orientation of the piezoelectric device 200′.

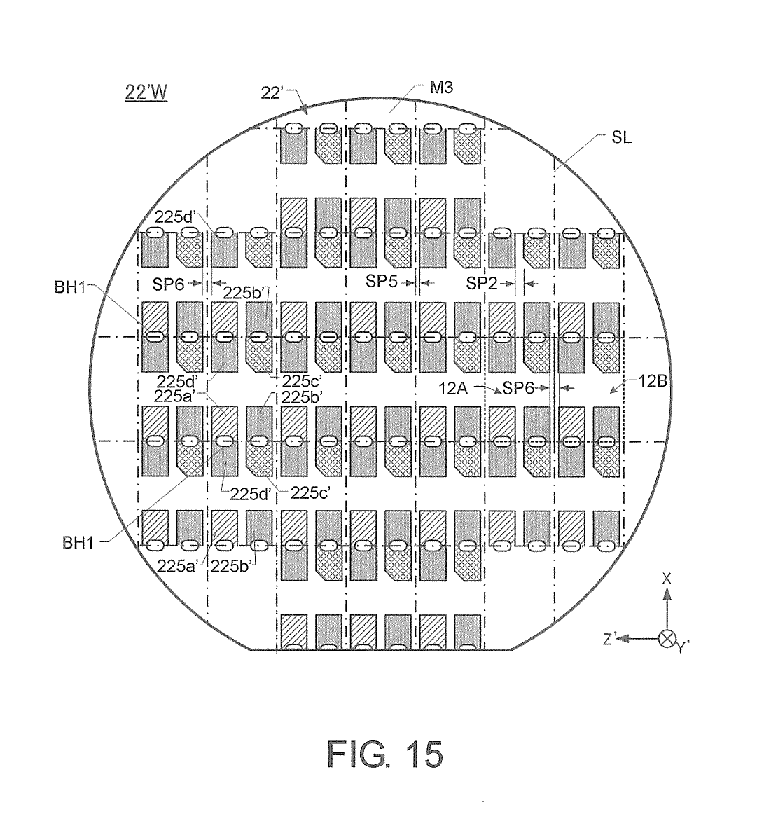

The method for fabricating the second piezoelectric device 200′ is approximately the same as the fabrication method of the second Embodiment. However, when the quartz-crystal vibrating piece 20′ is formed in a state of the quartz-crystal wafer 20W, as illustrated in FIG. 14, a distance between the adjacent quartz-crystal vibrating pieces 20′ differs. Additionally, when the base portion 22′ is formed in a state of the base wafer 22′W, as illustrated in FIG. 15, a distance from the adjacent base portions 22′ differs.

In step S102 of FIG. 3, the extraction electrodes 203a′ and 203b′ are formed from adjacent extraction electrodes 203a′ and 203b′ by a distance SP6 (see FIG. 14). The distance SP6 is approximately 40 μm to 100 μm. For example, assume that the distance SP6 is 40 μm and dicing width diced in step S17 is also 40 μm, the distance SP5 illustrated in FIG. 12A and FIG. 12B becomes 0 μm.

In step S122 of FIG. 3, the mounting terminal of the base portion 12B illustrated in FIG. 15 is formed from the mounting terminal formed at the base portion 12A adjacent in the Z′-axis direction by the distance SP6. Here, the distance SP6 is approximately 40 μm to 100 μm. Similarly, for example, assume that the distance SP6 is 40 μm, dicing width diced in step S17 also becomes 40 μm, the distance SP5 illustrated in FIG. 15 becomes 0 μm.

Representative embodiments are described in detail above; however, as will be evident to those skilled in the relevant art, this disclosure may be changed or modified in various ways within its technical scope.

While in this disclosure, for example, a base wafer, a quartz-crystal wafer, and a lid wafer are bonded together using low-melting point glass, a polyimide resin may be employed instead of the low-melting point glass. When using polyimide resin, the fabrication process may employ screen-printing, and an exposure step may be performed after applying photolithographic polyimide resin on the entire surface.

While in this application, a quartz-crystal vibrating piece is used, piezoelectric materials such as lithium tantalate and lithium niobate may be used in addition to quartz-crystal. Further, this disclosure may be directed to a piezoelectric oscillator in which an IC accommodating an oscillator circuit is mounted inside the package as a piezoelectric device.

In the first aspect, the piezoelectric device according to a second aspect is configured as follows. The two pairs of mounting terminals include a pair of external electrodes energized outside and a pair of grounding electrodes employed for grounding. The pair of external electrodes and the pair of grounding electrodes are diagonally formed on the second surface. In the first or second aspect, the piezoelectric device according to a third aspect is configured as follows. The base portion includes a depressed portion depressed from the first surface. The piezoelectric vibrating piece is disposed at the base portion with a conductive adhesive such that the pair of extraction electrodes and the pair of connecting electrodes are connected together.

In the third aspect, the piezoelectric device according to a fourth aspect is configured as follows. The piezoelectric device further includes a rectangular lid portion bonded to the first surface of the base portion. The lid portion and the base portion are bonded together with a sealing material. In the first or second aspect, the piezoelectric device according to a fifth aspect is configured as follows. The piezoelectric vibrating piece includes a vibrator and a rectangular framing body. The vibrator includes the pair of excitation electrodes. The rectangular framing body includes the extraction electrodes. The framing body surrounds a peripheral area of the vibrator. The piezoelectric vibrating piece is disposed such that the pair of extraction electrodes and the pair of connecting electrodes are connected together.

In the fifth aspect, the piezoelectric device according to a sixth aspect is configured as follows. The piezoelectric device further includes a lid portion that is bonded to one principal surface of the framing body. The lid portion is bonded to the one principal surface of the framing body with sealing material. The base portion is bonded to another principal surface of the framing body with sealing material. In any one of the first to sixth aspect, the piezoelectric device according to a seventh aspect is configured as follows. The first surface and the second surface are connected at a side surface of the castellation. The castellation has a cross section that includes a projecting portion. The projecting portion is protruded outside at the center portion from the first surface to the second surface.

With the fabrication method according to the embodiments, a piezoelectric device where a corner portion of a base portion is less damaged is obtained.

The principles, preferred embodiment and mode of operation of the present invention have been described in the foregoing specification. However, the invention which is intended to be protected is not to be construed as limited to the particular embodiments disclosed. Further, the embodiments described herein are to be regarded as illustrative rather than restrictive. Variations and changes may be made by others, and equivalents employed, without departing from the spirit of the present invention. Accordingly, it is expressly intended that all such variations, changes and equivalents which fall within the spirit and scope of the present invention as defined in the claims, be embraced thereby.

What is claimed is:

1. A piezoelectric device, comprising:
a piezoelectric vibrating piece that includes a pair of excitation electrodes on both principal surfaces, and a pair of extraction electrodes, the pair of extraction electrodes being extracted from the pair of excitation electrodes; and
a base portion in a square shape with four sides viewed from a first surface, the base portion including a pair of connecting electrodes and two pairs of mounting terminals, the pair of connecting electrodes being disposed on the first surface at a side of the piezoelectric vibrating piece and connected to the pair of extraction electrodes, the two pairs of mounting terminals being disposed on a second surface, the second surface being an opposite surface of the first surface, wherein
the base portion has two sides that face one another,
two pairs of castellations and two pairs of side surface electrodes are formed at the two sides, the two pairs of castellations are depressed toward a center side of the base portion, and the two pairs of side surface electrodes are on the two pairs of castellations, the two pairs of side surface electrodes connecting the first surface and the second surface,
one pair among the two pairs of side surface electrodes connects to the pair of connecting electrodes and one pair of mounting terminals among the two pairs of mounting terminals, and
the mounting terminals are formed up to four corners of the base portion.

2. The piezoelectric device according to claim 1, wherein
the two pairs of mounting terminals include a pair of external electrodes energized outside and a pair of grounding electrodes employed for grounding, and
the pair of external electrodes and the pair of grounding electrodes are diagonally formed on the second surface.

3. The piezoelectric device according to claim 1, wherein
the base portion includes a depressed portion depressed from the first surface, and
the piezoelectric vibrating piece is disposed at the base portion with a conductive adhesive such that the pair of extraction electrodes and the pair of connecting electrodes are connected together.

4. The piezoelectric device according to claim 3, further comprising:
a rectangular lid portion, bonded to the first surface of the base portion, and
the lid portion and the base portion are bonded together with a sealing material.

5. The piezoelectric device according to claim 1, wherein
the piezoelectric vibrating piece includes a vibrator and a rectangular framing body, the vibrator including the pair of excitation electrodes, the rectangular framing body including the extraction electrodes, the framing body surrounding a peripheral area of the vibrator, and
the piezoelectric vibrating piece is disposed such that the pair of extraction electrodes and the pair of connecting electrodes are connected together.

6. The piezoelectric device according to claim 5, further comprising:
a lid portion that is bonded to one principal surface of the framing body, wherein
the lid portion is bonded to the one principal surface of the framing body with sealing material, and
the base portion is bonded to another principal surface of the framing body with sealing material.

7. The piezoelectric device according to claim 1, wherein
the first surface and the second surface are connected at a side surface of the castellation, the castellation having a cross section that includes a projecting portion, the projecting portion being protruded outside at the center portion from the first surface to the second surface.
